(19) United States
(12) Patent Application Publication
(10) Pub. No.: US 2024/0379320 A1
(43) Pub. Date: Nov. 14, 2024

(54) ION IMPLANTATION SYSTEM AND RELATED METHODS

(71) Applicant: ENTEGRIS, INC., Billerica, MA (US)

(72) Inventors: Ying Tang, Brookfield, CT (US); Joseph R. Despres, Middletown, CT (US); Nicholas Harris, Danbury, CT (US); Edward E. Jones, Woodbury, CT (US)

(21) Appl. No.: 18/657,535

(22) Filed: May 7, 2024

Related U.S. Application Data
(60) Provisional application No. 63/464,844, filed on May 8, 2023.

(51) Int. Cl. H01J 37/08; H01J 37/317

(52) U.S. Cl. CPC H01J 37/08; H01J 37/3171; H01J 2237/006; H01J 2237/0815

(57) ABSTRACT

An ion implantation system and related methods are provided herein. An ion implantation system comprises a gas supply assembly comprising at least one gas supply vessel in fluid communication with an arc chamber. The gas supply assembly is configured to supply a gas component comprising at least one of GeF₄, GeH₄, H₂, a fluorine-containing gas, or any combination thereof. When the gas component is supplied from the at least one gas supply vessel to the arc chamber for implantation into a substrate, a beam current of Ge ions generated from the gas component is greater than a beam current of Ge ions generated from a control gas component.

### FIELD

The present disclosure relates to the field of ion implantation systems and methods.

### BACKGROUND

Ion implantation involves implantation of a chemical species into a substrate, such as a microelectronic device wafer, by impingement of energetic ions of such species onto the substrate. In order to generate the ionic implantation species, the dopant gas is ionized to generate an ion beam.

### SUMMARY

Some embodiments relate to an ion implantation system. In some embodiments, the ion implantation system comprises a gas supply assembly. In some embodiments, the gas supply assembly comprises at least one gas supply vessel in fluid communication with an arc chamber. In some embodiments, the gas supply assembly is configured to supply a gas component comprising at least one of GeF₄, GeH₄, H₂, a fluorine-containing gas, or any combination thereof. In some embodiments, when the gas component is supplied from the at least one gas supply vessel to the arc chamber for implantation into a substrate, a beam current of Ge ions generated from the gas component is greater than a beam current of Ge ions generated from a control gas component.

Some embodiments relate to a method of ion implantation. In some embodiments, the method comprises flowing a gas component into an arc chamber. In some embodiments, the gas component comprises at least one of GeF₄, GeH₄, H₂, a fluorine-containing gas, or any combination thereof. In some embodiments, the method comprises generating Ge ions from the gas component for implantation into a substrate. In some embodiments, a beam current of the Ge ions generated from the gas component is greater than a beam current of Ge ions generated from a control gas component.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 depicts a schematic representation of an ion implantation system, according to some embodiments.

FIG. 2 is a flow chart of a method for ion implantation, according to some embodiments.

FIG. 3A is a graph showing changes in beam current at different gas flow rates of GeF₄, according to some embodiments.

FIG. 3B is a graph showing the beam spectrum of GeF₄ according to some embodiments.

FIG. 3C is a graph showing the beam spectrum of W⁺ and WFₓ⁺ of FIG. 3B, according to some embodiments.

FIG. 4A is a graph showing changes in beam current at different gas flow rates of a GeH₄ and GeF₄ gas mixture, according to some embodiments.

FIG. 4B is a graph showing the beam spectrum of a GeH₄ and GeF₄ gas mixture, according to some embodiments.

FIG. 4C is a graph showing the beam spectrum of W⁺ and WFₓ⁺ of FIG. 4B, according to some embodiments.

FIG. 4D is a graph showing the beam spectrum of a GeH₄ and GeF₄ gas mixture, according to some embodiments.

FIG. 4E is a graph showing the beam spectrum of W⁺ and WFₓ⁺ of FIG. 4D, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Some embodiments relate to ion implantation systems and related methods. As disclosed herein, at least one advantage of the present disclosure is that the ion implantation systems (and related methods) disclosed herein unexpectedly exhibit enhanced beam currents. At least one additional advantage of the present disclosure is that the ion implantation systems (and related methods) disclosed herein unexpectedly exhibit a longer source life. For example, as disclosed herein, in some embodiments, when the ion implantation systems (and related methods) employ at least one of a gas component, a target material comprising Ge, or any combination thereof, the ion implantation systems exhibit an enhanced ion beam current and/or source life.

As used herein, “isotopically-enriched” may refer to a germanium isotope. For example, germanium has five naturally occurring isotopes that are ⁷⁰Ge, ⁷²Ge, ⁷³Ge, ⁷⁴Ge, and ⁷⁶Ge. ⁷⁴Ge is the most common germanium isotope, with a natural abundance of 36.28%. This is followed by ⁷²Ge with a natural abundance of 27.54%, ⁷⁰Ge with a natural abundance of 20.84%, ⁷³Ge with a natural abundance of 7.73%, and by ⁷⁶Ge with a natural abundance of 7.61%. For example, in some embodiments, the term refers to a material in which a germanium isotope is present above natural abundance levels. As another example, isotopically-enriched GeF₄ gas may comprise at least germanium isotopically enriched with the ⁷²Ge isotope, such as enriched to an amount greater than 50% of the total amount of germanium isotopes. As another example, an isotopically-enriched GeH₄ gas may comprise at least germanium isotopically enriched with the ⁷²Ge isotope, such as enriched to an amount greater than 50% of the total amount of germanium isotopes. As another example, isotopically-enriched Ge may comprise at least germanium isotopically enriched with the ⁷²Ge isotope, such as enriched to an amount greater than 50% of the total amount of germanium isotopes. In some embodiments, an isotopically enriched germanium isotope includes germanium isotopically enriched above natural abundance levels, up to 100% above natural abundance levels. In some embodiments, an isotopically enriched germanium isotope includes germanium isotopically enriched in a germanium isotope above natural abundance levels, up to 100% above natural abundance levels. In some embodiments, isotopically-enriched Ge may comprise isotopically-enriched solid germanium. In some embodiments, the isotopically-enriched solid germanium comprises at least germanium isotopically enriched with at least one of ⁷⁰Ge, ⁷²Ge, ⁷³Ge, ⁷⁴Ge, ⁷⁶Ge, or any combination thereof.

As used herein, GeF₄ may be used as a “dopant gas” which refers to a gas-phase material including the germanium dopant species, i.e., the species to be implanted on the substrate in the ion implantation system. The fluorine of GeF₄ may be referred to as the non-dopant component of the GeF₄ dopant gas. In some embodiments, the dopant gas consists of GeF₄, or consists essentially of GeF₄ (i.e., where there is less than 10% volume of any other one or more dopant gas species that are different than GeF₄, as measured relative to the amount of GeF₄). In some embodiments, GeF₄ may be used with one or more other different dopant gas species, such as germane, boron trifluoride, diborane, silicon tetrafluoride, silane, phosphine, and arsine. If one or more different dopant gas species are used, GeF₄ may be the predominant gas species used in the system (i.e., used in an amount greater than any other dopant gas species).

As used herein, GeH₄ may be used as a “dopant gas” which refers to a gas-phase material including the germanium dopant species, i.e., the species to be implanted on the substrate in the ion implantation system. The hydrogen of GeH₄ may be referred to as the non-dopant component of the GeH₄ dopant gas. In some embodiments, the dopant gas consists of GeH₄, or consists essentially of GeH₄ (i.e., where there is less than 20% volume of any other one or more dopant gas species that are different than GeH₄, as measured relative to the amount of GeH₄). In some embodiments, GeH₄ may be used with one or more other different dopant gas species, such as germanium tetrafluoride, boron trifluoride, diborane, silicon tetrafluoride, silane, phosphine, and arsine. If one or more different dopant gas species are used, GeH₄ may be the predominant gas species used in the system (i.e., used in an amount greater than any other dopant gas species).

In some embodiments, the GeF₄ gas that is used may be based on a natural isotopic composition of Ge, or may be isotopically-enriched in a Ge isotope (e.g., above natural abundance levels). In some embodiments, the gas supply vessel or the gas supply vessels may comprise a natural isotopic distribution of Ge in the GeF₄ as the dopant gas, or the GeF₄ may be isotopically enriched in at least one Ge isotope above natural abundance levels.

In some embodiments, the GeH₄ gas that is used may be based on a natural isotopic composition of Ge, or may be isotopically-enriched in a Ge isotope (e.g., above natural abundance levels). In some embodiments, the gas supply vessel or the gas supply vessels may comprise a natural isotopic distribution of Ge in the GeH₄ as the dopant gas, or the GeH₄ may be isotopically enriched in at least one Ge isotope above natural abundance levels.

In some embodiments, the dopant gas source includes one or more ionizable germanium containing gases including, but not limited to, GeF₄, Ge₂F₆, GeH₄, Ge₂H₆, GeHF₃, GeH₂F₂, and GeH₃F and any other germanium hydride fluoride gas(es).

As used herein, H₂ may be used as a “non-dopant gas” but may be effective when used with the GeF₄ gas or the GeH₄ gas to intercept the tungsten-fluorine reaction and reduce tungsten fluoride formation. Use of H₂ according to embodiments here, may provide other benefits such as improving Get beam current gain and W⁺ peak reduction during ion implantation. In some embodiments, the non-dopant gas comprises H₂, or consists essentially of H₂ (i.e., where there is less than 1% volume of any other one or more non-dopant gas species that are different than H₂, as measured relative to the amount of H₂). In some embodiments, H₂ may be used with one or more other different non-dopant gas species such as helium, nitrogen, neon, argon, xenon, and krypton. Such other non-dopant gas species may be described as “a diluent gas” or a “supplemental gas” or a “co-species gas.” If one or more different non-dopant gas species are used, H₂ may be the predominant gas species used in the system (i.e., used in an amount greater than any other optional non-dopant gas species).

In some embodiments, use of at least one of GeF₄, GeH₄, a target material comprising Ge, or any combination thereof, as dopant gases, show enhanced beam currents and/or longer source life. In some embodiments, use of at least one of GeF₄, GeH₄, a target material comprising Ge, or any combination thereof, as dopant gases, show reduced tungsten which improves beam source life because tungsten can contribute to the accumulation of deposits on cathode surfaces. Deposits on cathode surfaces negatively affect thermionic emission of ions resulting in lowered arc currents, reduced performance and shortened lifetime of the ion source, deleterious etching reactions from such dopant gases as a result of the generation of free fluorine in the arc chamber, as well as stripping or sputtering or depositing tungsten material of cathode resulting in loss of physical integrity of the cathode and consequent reduction of performance and lifetime of the ion source.

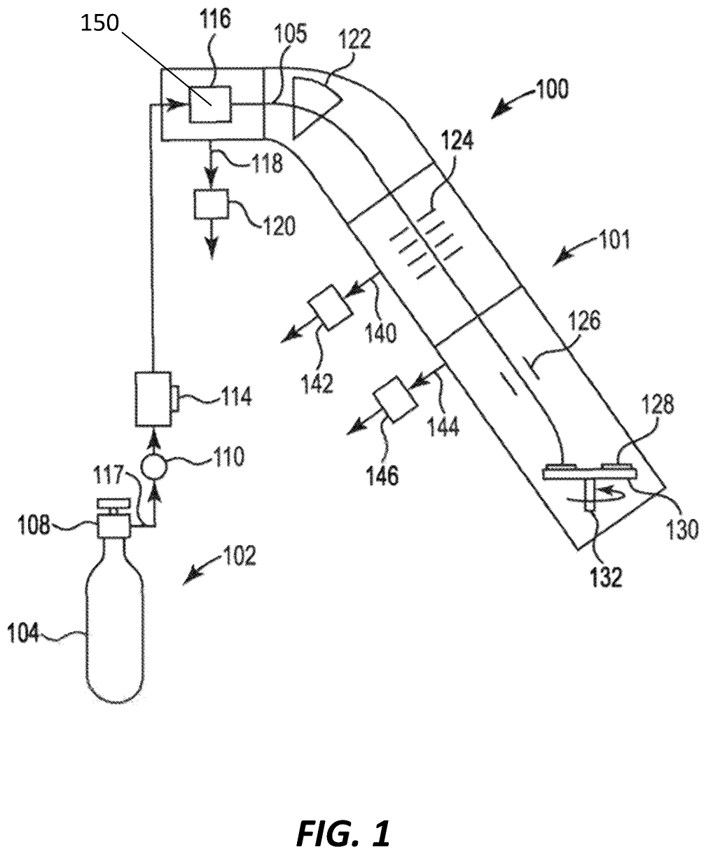

FIG. 1 depicts a schematic representation of an ion implantation system, according to some embodiments.

As shown in FIG. 1, the ion implantation system 100 includes an arc chamber 150 in fluid combination with at least one gas supply vessel 102. In some embodiments, the at least one gas supply vessel 102 is included in a gas supply assembly which is configured to supply a gas component. As shown, the ion implantation system 100 also includes an ion implant chamber 101.

In some embodiments, when the gas component is supplied from the at least one gas supply vessel 102 to the arc chamber 150, optionally in the presence of a target material comprising Ge, for implantation into a substrate, a beam current of Ge ions generated from the gas component is greater than a beam current of Ge ions generated from a control gas component. The control gas component can differ from the gas component in content (e.g., different volume percentages of gas/vapor species) and/or chemical species, among other things. In some embodiments, when the gas component is supplied from the at least one gas supply vessel 102 to the arc chamber 150, a beam current of Ge ions generated from the gas component, in the presence of a target material comprising Ge, is greater than a beam current of Ge ions generated from the gas component in the absence of the target material comprising Ge.

In some embodiments, the gas supply assembly and/or the at least one gas supply vessel is configured to supply a gas component comprising at least one of GeF₄, GeH₄, H₂, a fluorine-containing gas, or any combination thereof. In some embodiments, the at least one gas supply vessel 102 is a single vessel comprising at least one of GeF₄, GeH₄, H₂, a fluorine-containing gas, or any combination thereof. In some embodiments, the at least one gas supply vessel 102 comprises two or more vessels. In some embodiments, the at least one gas supply vessel 102 comprises at least one of a first vessel, a second vessel, a third vessel, a fourth vessel, or any combination thereof. In some embodiments, the first vessel comprises GeF₄. In some embodiments, the second vessel comprises GeH₄. In some embodiments, the third vessel comprises H₂. In some embodiments, the fourth vessel comprises the fluorine-containing gas. In some embodiments, the gas component comprises isotopically enriched GeF₄, wherein the GeF₄ is isotopically enriched in ⁷²Ge (or any of the other Ge isotopes disclosed herein). It will be appreciated that any one of the at least one gas supply vessels 102 disclosed herein may further comprise other gases and/or materials, such as, for example and without limitation, at least one of an ionizable gas, a diluent gas, a carrier gas, a co-gas, the like, or any combination thereof.

In some embodiments, the gas supply vessel 102 comprises a single vessel comprising a mixture of dopant gases, such as GeF₄ and GeH₄. In some embodiments, the GeF₄ is isotopically-enriched. In some embodiments, the GeH₄ is isotopically-enriched. In some embodiments, the gas supply vessel 102 comprises two vessels, such that each vessel individually contains a single dopant gas. For example, one vessel may comprise GeF₄ and the other vessel may comprise GeH₄. In some embodiments, the gas supply vessel 102 comprises multiple vessels, such that each vessel contains a single dopant gas. In some embodiments, an individual vessel of one or more vessels comprises more than one dopant gas, such that the vessel comprises a mixture of dopant gases. In some embodiments, the gas supply vessel 102 is configured to deliver a dopant gas subatmospherically via one or more pressure reduction regulators. In some embodiments, a dopant gas is delivered subatmospherically through the use of an adsorbent.

In some embodiments, the ion implantation system 100 is configured to supply a gas of 20% to 95% by volume of GeF₄ based on a total volume of the gas mixture, or any range or subrange between 20% to 95%. For example, in some embodiments, the percent by volume of GeF₄ based on a total volume of the gas mixture may be 20% to 90%, 30% to 90%, 40% to 90%, 50% to 90%, 60% to 80%, 70% to 90% or 80% to 90%. In some embodiments, the percent by volume of GeF₄ based on a total volume of the gas mixture may be 30% to 50%, or any subrange between 30% to 50%. In some embodiments, the percent by volume of GeF₄ based on a total volume of the gas mixture may be 31% to 50%, 32% to 50%, 33% to 50%, 34% to 50%, 35% to 50%, 36% to 50%, 37% to 50%, 38% to 50%, 39% to 50%, 40% to 50%, 41% to 50%, 42% to 50%, 43% to 50%, 44% to 50%, 45% to 50%, 46% to 50%, 47% to 50%, 48% to 50%, or 49% to 50%. In some embodiments, the percent by volume of GeF₄ based on a total volume of the gas mixture may be 30% to 49%, 30% to 48%, 30% to 47%, 30% to 46%, 30% to 45%, 30% to 44%, 30% to 43%, 30% to 42%, 30% to 41%, 30% to 40%, 30% to 39%, 30% to 38%, 30% to 37%, 30% to 36%, 30% to 35%, 30% to 34%, 30% to 33%, 30% to 32%, or 30% to 31%.

In some embodiments, the gas supply vessel 102 comprises 5% to 80% by volume of GeH₄ based on a total volume of the gas mixture, or any range or subrange between 5% to 80%. For example, in some embodiments, the percent by volume of GeH₄ based on a total volume of the gas mixture may be 10% to 80%, 20% to 80%, 30% to 80%, 40% to 80%, 50% to 80%, 60% to 80%, or 70% to 80%. In some embodiments, the percent by volume of GeH₄ based on a total volume of the gas mixture may be 10% to 50%, 15% to 50%, 20% to 50%, 25% to 50%, 30% to 50%, 35% to 50%, 40% to 50%, or 45% to 50%. In some embodiments, the percent by volume of GeH₄ based on a total volume of the gas mixture may be 11% to 80%, 12% to 80%, 13% to 80%, 14% to 80%, 15% to 80%, 16% to 80%, 17% to 80%, 18% to 80%, 19% to 80%, 20% to 80%, 21% to 80%, 22% to 80%, 23% to 80%, 24% to 80%, 25% to 80%, 26% to 80%, 27% to 80%, 28% to 80%, 29% to 80%, 30% to 80%, 31% to 80%, 32% to 80%, 33% to 80%, 34% to 80%, 35% to 80%, 36% to 80%, 37% to 80%, 38% to 80%, 39% to 80%, 40% to 80%, 41% to 80%, 42% to 80%, 43% to 80%, 44% to 80%, 45% to 80%, 46% to 80%, 47% to 80%, 48% to 80%, 49% to 80%, 50% to 80%, 51% to 80%, 52% to 80%, 53% to 80%, 54% to 80%, 55% to 80%, 56% to 80%, 57% to 80%, 58% to 80%, 59% to 80%, 60% to 80%, 61% to 80%, 62% to 80%, 63% to 80%, 64% to 80%, 65% to 80%, 66% to 80%, 67% to 80%, 68% to 80%, 69% to 80%, 70% to 80%, 71% to 80%, 72% to 80%, 73% to 80%, 74% to 80%, or 75% to 80%, 76% to 80%, 77% to 80%, 78% to 80%, or 79% to 80%. In some embodiments, the percent by volume of GeH₄ based on a total volume of the gas mixture may be 10% to 89%, 10% to 88%, 10% to 87%, 10% to 86%, 10% to 85%, 10% to 84%, 10% to 83%, 10% to 82%, 10% to 81%, 10% to 80%, 10% to 79%, 10% to 78%, 10% to 77%, 10% to 76%, 10% to 75%, 10% to 74%, 10% to 73%, 10% to 72%, 10% to 71%, 10% to 70%, 10% to 69%, 10% to 68%, 10% to 67%, 10% to 66%, 10% to 65%, 10% to 64%, 10% to 63%, 10% to 62%, 10% to 61%, 10% to 60%, 10% to 59%, 10% to 58%, 10% to 57%, 10% to 56%, 10% to 55%, 10% to 54%, 10% to 53%, 10% to 52%, 10% to 51%, 10% to 50%, 10% to 49%, 10% to 48%, 10% to 47%, 10% to 46%, 10% to 45%, 10% to 44%, 10% to 43%, 10% to 42%, 10% to 41%, 10% to 40%, 10% to 39%, 10% to 38%, 10% to 37%, 10% to 36%, 10% to 35%, 10% to 34%, 10% to 33%, 10% to 32%, 10% to 31%, 10% to 30%, 10% to 29%, 10% to 28%, 10% to 27%, 10% to 26%, 10% to 25%, 10% to 24%, 10% to 23%, 10% to 22%, 10% to 21%, 10% to 20%, 10% to 19%, 10% to 18%, 10% to 17%, 10% to 16%, 10% to 15%, 10% to 14%, 10% to 13%, 10% to 12%, or 10% to 11%.

In some embodiments, the gas supply vessel 102 comprises H₂. In some embodiments, the gas supply vessel 102 is a device configured to generate hydrogen via an electrochemical cell.

In some embodiments, the gas supply vessel 102 comprises a fluoride gas. The fluoride gas may comprise at least one of BF₃, NF₃, PF₃, PF₅, GeF₄, XeF₂, CF₄, B₂F₄, SiF₄, Si₂F₆, AsF₃, AsF₅, XeF₄, XeF₆, WF₆, MoF₆, CₙF₂ₙ₊₂, CₙF₂ₙ, CₙF₂ₙ₋₂, CₙHₓF₂ₙ₊₂₋ₓ, CₙHₓF₂ₙ₋ₓ, CₙHₓF₂ₙ₋₂₋ₓ, COF₂, SF₆, SF₄, SeF₆, N₂F₄, HF, F₂, or any combination thereof. In some embodiments, n is 1 or greater (e.g., 1-10). In some embodiments, x is 1 or greater (e.g., 1-10). In some embodiments, n and x are different. In some embodiments, n and x are the same.

In some embodiments, the arc chamber 150 contains a target material comprising Ge. The target material comprising Ge may comprise at least one of a pure germanium, a germanium isotope, a silicon germanium (e.g., Si₁₋ₓGeₓ where 0<x<1), or any combination thereof. In some embodiments, the target material comprising Ge is enriched in a germanium isotope.

In some embodiments, the arc chamber 150 includes arc chamber walls with interior-plasma facing surfaces. There may be one or more arc chamber liners configured to contact all or a portion of the interior-plasma facing surfaces of the walls of the arc chamber 150. In some embodiments, the arc chamber 150 contains a liner comprising Ge.

In some embodiments, the arc chamber 150 comprises a target material comprising Ge. In some embodiments, the target material comprising Ge is enriched in a germanium isotope. In some embodiments, the arc chamber 150 comprises a container comprising Ge. The container may itself comprise Ge. For example, in some embodiments, the container is constructed of Ge. In some embodiments, the container itself does not comprise Ge but is configured to hold or contain the target material comprising Ge. The container may be configured to withstand high temperatures within the arc chamber 150 such that it does not melt and sufficiently retains its shape during the ion implantation process. In some embodiments, the container may be attached to or placed on the surface of the anti-cathode (or call repeller), wall of the arc chamber 150, or arc chamber liners. For example, in some embodiments, the container comprising Ge is located on at least one of a surface of an anti-cathode, a surface of an arc chamber wall, a surface of an arc chamber liner, or any combination thereof. In some embodiments, the arc chamber 150 comprises a container comprising at least one of a solid Ge, a liquid Ge, or any combination thereof. In some embodiments, the arc chamber 150 is at least partially formed of a target material comprising Ge. In some embodiments, the arc chamber 150 comprises a container of a target material comprising Ge. In some embodiments, the arc chamber 150 comprises a liner at least partially formed of a target material comprising Ge. Any of the target materials comprising Ge may be isotopically enriched in a germanium isotope above natural abundance levels. In some embodiments, for example and without limitation, the target material comprising Ge comprises isotopically enriched germanium, wherein the isotopically enriched germanium is isotopically enriched in ⁷²Ge (or any of the other isotopes disclosed herein).

As shown in FIG. 1, the gas supply vessel 102 may have an interior volume holding at least one of GeF₄, GeH₄, or any combination thereof, that is supplied for ion implantation of a substrate 128 in the illustrated ion implant chamber 101.

The storage and gas supply vessel 102 may be of a type containing a sorbent medium on which the dopant gas is physically adsorbed for storage of the gas, with the gas being desorbed from the sorbent medium, under dispensing conditions, for discharge from the gas supply vessel 102. The sorbent medium may be a solid-phase carbon adsorbent material. In some embodiments, the sorbent medium comprises at least one of a porous organic polymer (POP), a zeolite, a zeolitic imidazolate framework (ZIF), a silicalite, a metal-organic framework (MOF), or any combination thereof. Further non-limiting examples of sorbent materials are described in U.S. Patent Application Publication No. 2023/0079446, entitled Composite Adsorbent-Containing Bodies and Related Methods, which is incorporated by reference herein in its entirety. Sorbent-based vessels of such type are commercially available from Entegris. Inc. (Danbury, Conn., USA) under the trademarks SDS and SAGE. Alternatively, the vessel may be of an internally pressure-regulated type, containing one or more pressure regulators in the interior volume of the vessel. Such pressure-regulated vessels are commercially available from Entegris, Inc. (Danbury, Conn., USA) under the trademark VAC. As a still further alternative, the vessel may contain the dopant source material in a solid form that is volatilized, e.g., by heating of the vessel and/or its contents, to generate the dopant gas as a vaporization or sublimation product.

The storage and gas supply vessel 102 may include a cylindrical vessel wall 104 enclosing an interior volume holding the mixture of the GeF₄ and GeH₄ gases in an adsorbed state, a free gas state, or a liquefied gas state, or a mixture thereof.

The gas supply vessel 102 may include a valve head 108 coupled in gas flow communication via a dispensing line 117. A pressure sensor 110 may be disposed in the line 117, together with a mass flow controller 114; other optional monitoring and sensing components may be coupled with the line, and interfaced with control means such as actuators, feedback and computer control systems, cycle timers, etc.

The ion implant chamber 101 may contain an ion source 116 receiving the dispensed mixture of the GeF₄ and GeH₄ gases from line 117 and generates an ion beam 105. The ion beam 105 may pass through the mass analyzer unit 122 which selects the ions needed and rejects the non-selected ions.

The selected ions may pass through the acceleration electrode array 124 and then the deflection electrodes 126. The resulting focused ion beam may be impinged on the substrate element 128 disposed on the rotatable holder 130 mounted on spindle 132. The ion beam of dopant ions may be used to dope the substrate as desired to form a doped structure.

The respective sections of the ion implant chamber 101 may be exhausted through lines 118, 140 and 144 by means of pumps 120, 142 and 146, respectively.

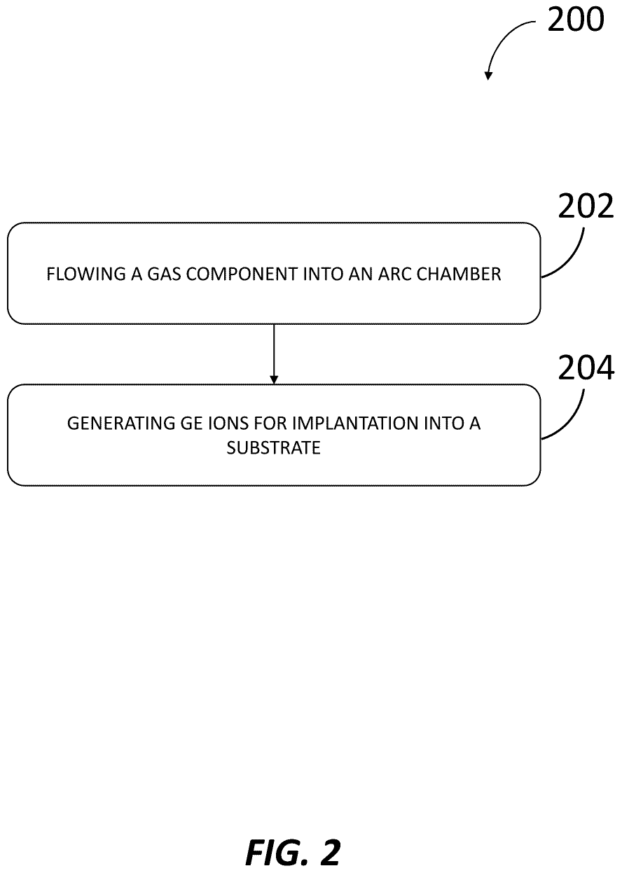

FIG. 2 is a flow chart of a method 200 for ion implantation, according to some embodiments.

As shown in FIG. 2, the method 200 may comprise one or more of the following steps: a step 202 of flowing a gas component into an arc chamber; and a step 204 of generating Ge ions for implantation into a substrate.

In some embodiments, the arc chamber of step 202 may be the arc chamber 150 as described herein. The gas component may comprise the gases and/or vapors of the gas supply vessel 102 as described herein.

In some embodiments, step 202 further comprises flowing the gas component into the arc chamber. In some embodiments, the flowing is conducted at a predetermined flow rate. In some embodiments, the gas component is an ionizable gas mixture.

In some embodiments, the flowing of step 202 comprises flowing the ionizable gas mixture at a flowrate of 0.1 sccm to 5 sccm. In some embodiments, flowing the ionizable gas mixture may be at a flowrate of 0.5 sccm to 5 sccm, 1 sccm to 5 sccm, 1.5 sccm to 5 sccm, 2 sccm to 5 sccm, 2.5 sccm to 5 sccm, 3 sccm to 5 sccm, 3.5 sccm to 5 sccm, 4 sccm to 5 sccm, or 4.5 sccm to 5 sccm. In some embodiments, flowing the ionizable gas mixture may be at a flowrate of 0.1 sccm to 5 sccm, 0.2 sccm to 5 sccm, 0.3 sccm to 5 sccm, 0.4 sccm to 5 sccm, 0.5 sccm to 5 sccm, 0.6 sccm to 5 sccm, 0.7 sccm to 5 sccm, 0.8 sccm to 5 sccm, 0.9 sccm to 5 sccm, 1 sccm to 5 sccm, 1.1 sccm to 5 sccm, 1.2 sccm to 5 sccm, 1.3 sccm to 5 sccm, 1.4 sccm to 5 sccm, 1.5 sccm to 5 sccm, 1.6 sccm to 5 sccm, 1.7 sccm to 5 sccm, 1.8 sccm to 5 sccm, 1.9 sccm to 5 sccm, 2 sccm to 5 sccm, 2.1 sccm to 5 sccm, 2.2 sccm to 5 sccm, 2.3 sccm to 5 sccm, 2.4 sccm to 5 sccm, 2.5 sccm to 5 sccm, 2.6 sccm to 5 sccm, 2.7 sccm to 5 sccm, 2.8 sccm to 5 sccm, 2.9 sccm to 5 sccm, 3 sccm to 5 sccm, 3.1 sccm to 5 sccm, 3.2 sccm to 5 sccm, 3.3 sccm to 5 sccm, 3.4 sccm to 5 sccm, 3.5 sccm to 5 sccm, 3.6 sccm to 5 sccm, 3.7 sccm to 5 sccm, 3.8 sccm to 5 sccm, 3.9 sccm to 5 sccm, 4 sccm to 5 sccm, 4.1 sccm to 5 sccm, 4.2 sccm to 5 sccm, 4.3 sccm to 5 sccm, 4.4 sccm to 5 sccm, 4.5 sccm to 5 sccm, 4.6 sccm to 5 sccm, 4.7 sccm to 5 sccm, 4.8 sccm to 5 sccm, or 4.9 sccm to 5 sccm. In some embodiments, flowing the GeF₄ may be at a flowrate of 0.1 sccm to 5 sccm, 0.1 sccm to 4.9 sccm, 0.1 sccm to 4.8 sccm, 0.1 sccm to 4.7 sccm, 0.1 sccm to 4.6 sccm, 0.1 sccm to 4.5 sccm, 0.1 sccm to 4.4 sccm, 0.1 sccm to 4.3 sccm, 0.1 sccm to 4.2 sccm, 0.1 sccm to 4.1 sccm, 0.1 sccm to 4 sccm, 0.1 sccm to 3.9 sccm, 0.1 sccm to 3.8 sccm, 0.1 sccm to 3.7 sccm, 0.1 sccm to 3.6 sccm, 0.1 sccm to 3.5 sccm, 0.1 sccm to 3.4 sccm, 0.1 sccm to 3.3 sccm, 0.1 sccm to 3.2 sccm, 0.1 sccm to 3.1 sccm, 0.1 sccm to 3 sccm, 0.1 sccm to 2.9 sccm, 0.1 sccm to 2.8 sccm, 0.1 sccm to 2.7 sccm, 0.1 sccm to 2.6 sccm, 0.1 sccm to 2.5 sccm, 0.1 sccm to 2.4 sccm, 0.1 sccm to 2.3 sccm, 0.1 sccm to 2.2 sccm, 0.1 sccm to 2.1 sccm, 0.1 sccm to 2 sccm, 0.1 sccm to 1.9 sccm, 0.1 sccm to 1.8 sccm, 0.1 sccm to 1.7 sccm, 0.1 sccm to 1.6 sccm, 0.1 sccm to 1.5 sccm, 0.1 sccm to 1.4 sccm, 0.1 sccm to 1.3 sccm, 0.1 sccm to 1.2 sccm, 0.1 sccm to 1.1 sccm, 0.1 sccm to 1 sccm, 0.1 sccm to 0.9 sccm, 0.1 sccm to 0.8 sccm, 0.1 sccm to 0.7 sccm, 0.1 sccm to 0.6 sccm, 0.1 sccm to 0.5 sccm, 0.1 sccm to 0.4 sccm, 0.1 sccm to 0.3 sccm, or 0.1 sccm to 0.2 sccm.

In some embodiments, the generating of step 204 comprises generating Ge ions for implantation into the substrate.

In some embodiments, the substrate of step 204 may comprise, consist of, or consist essentially of at least one of Si, Co, Cu, AI, W, WN, WC, TIN, Mo, MOC, SiO₂, W, SiN, WCN, Al₂O₃, AlN, ZrO₂, La₂O₃, TaN, RuO₂, IrO₂, Nb₂O₃, Y₂O₃, hafnium oxide, or any combination thereof. In some embodiments, the substrate may comprise a silicon-containing film. In some embodiments, the silicon-containing film may comprise, consist of, or consist essentially of at least one of at least one of silicon, silicon nitride, silicon oxynitride, silicon oxide, silicon dioxide, silicon carbide, silicon carbonitride, silicon oxycarbonitride, carbon-doped silicon nitride, carbon-doped silicon oxide, carbon-doped silicon oxynitride, or any combination thereof. In some embodiments, the substrate may comprise other silicon-based substrates, such as, for example, one or more of polysilicon substrates, metallic substrates, and dielectric substrates.

Some embodiments relate to an ion implantation system. In some embodiments, the ion implantation system may comprise the arc chamber 150 described herein. In some embodiments, the ion implantation system may comprise the gas supply vessel 102 described herein. In some embodiments, the gas supply vessel 102 comprises a Ge gas. In some embodiments, the Ge gas comprises at least one of GeF₄, GeH₄, or any combination thereof. In some embodiments, the arc chamber comprises a target material comprising Ge. In some embodiments, the target material comprising Ge is the target material described herein. In some embodiments, when the Ge gas is supplied for implantation into a substrate in the presence of the target material, a beam current of the Ge gas is at least 10% greater than a beam current of the Ge gas in the absence of the target material. In some embodiments, the Ge ions are generated without applying a bias voltage.

It will be appreciated that any one or more of the embodiments disclosed herein may be employed in alone or in combination, without departing from the scope of this disclosure.

### Example 1

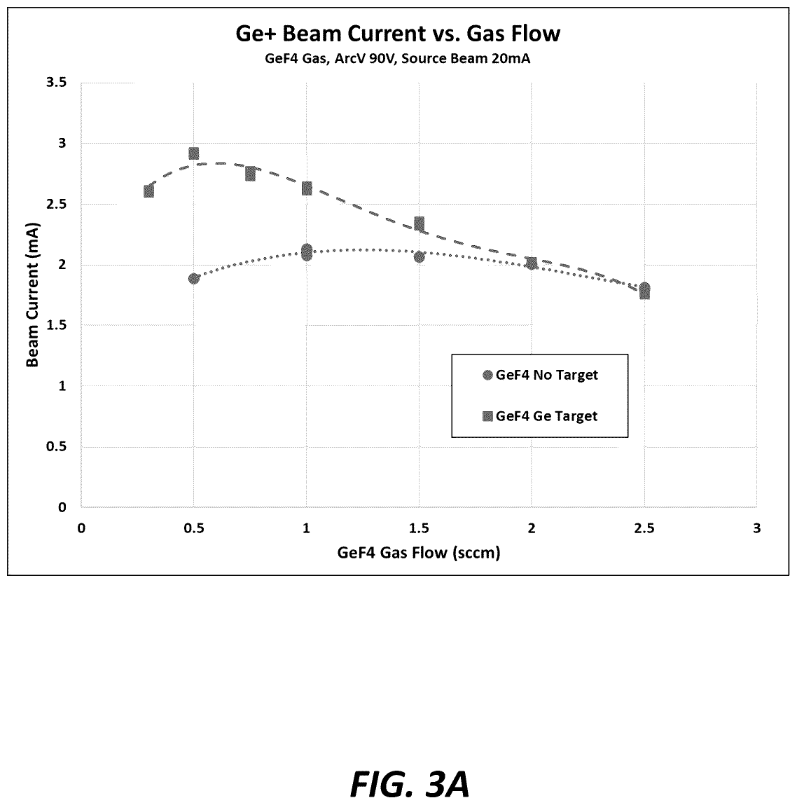

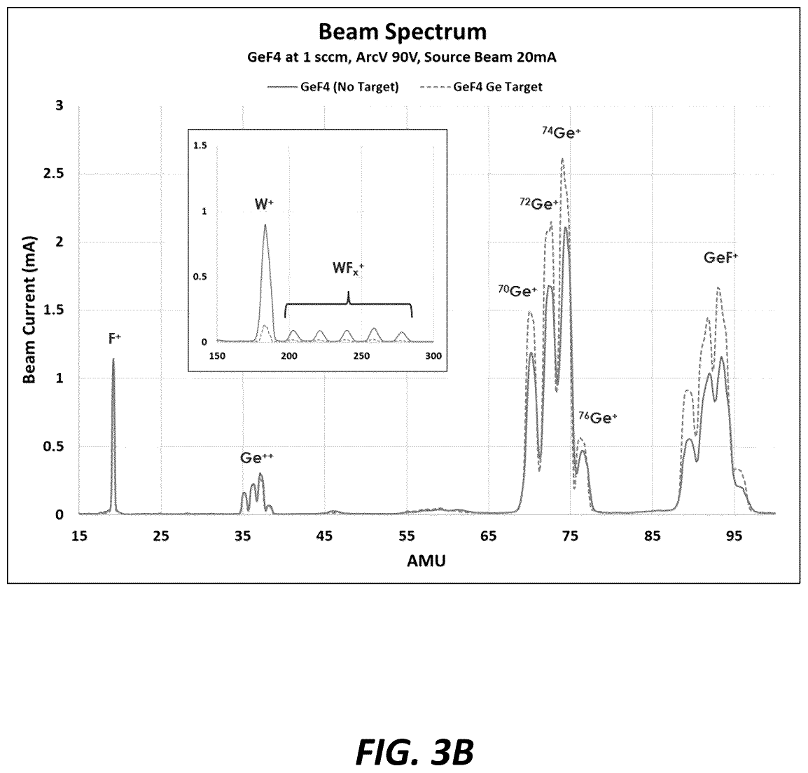

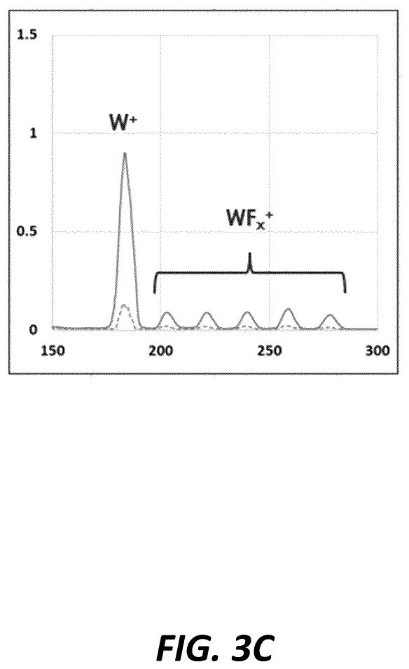

GeF₄ was flowed into an arc chamber containing a target material comprising Ge at various flow rates. The performance of GeF₄ with the Ge target material was compared to a control composition of GeF₄ flowed into an arc chamber containing no target material. The beam current in mA was measured at different flow rates of GeF₄ as shown in FIG. 3A. As shown in FIG. 3A, the arc power was 90V and the source beam was 20 mA. As shown, the GeF₄ with the Ge target material showed markedly improved beam current relative to the control composition.

FIG. 3B is a graph showing the beam spectrum of GeF₄ with the Ge target material and the control composition. As shown in FIG. 3B, the GeF₄ with the Ge target material showed markedly improved beam current relative to the control composition. Furthermore, the GeF₄ with the Ge target material showed markedly reduced W⁺ and WFₓ⁺ peaks, as shown in FIG. 3C.

### Example 2

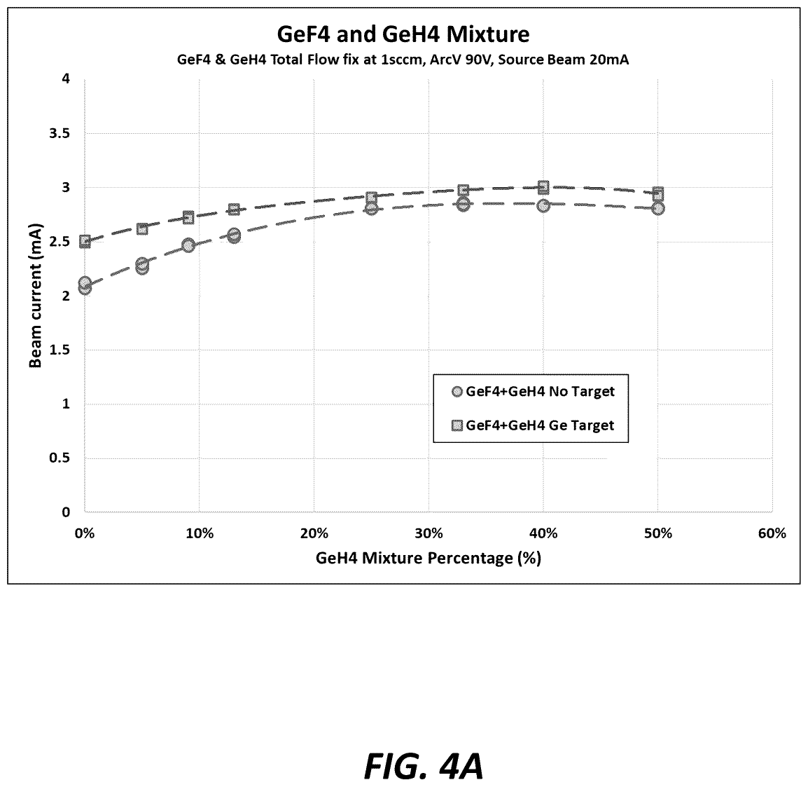

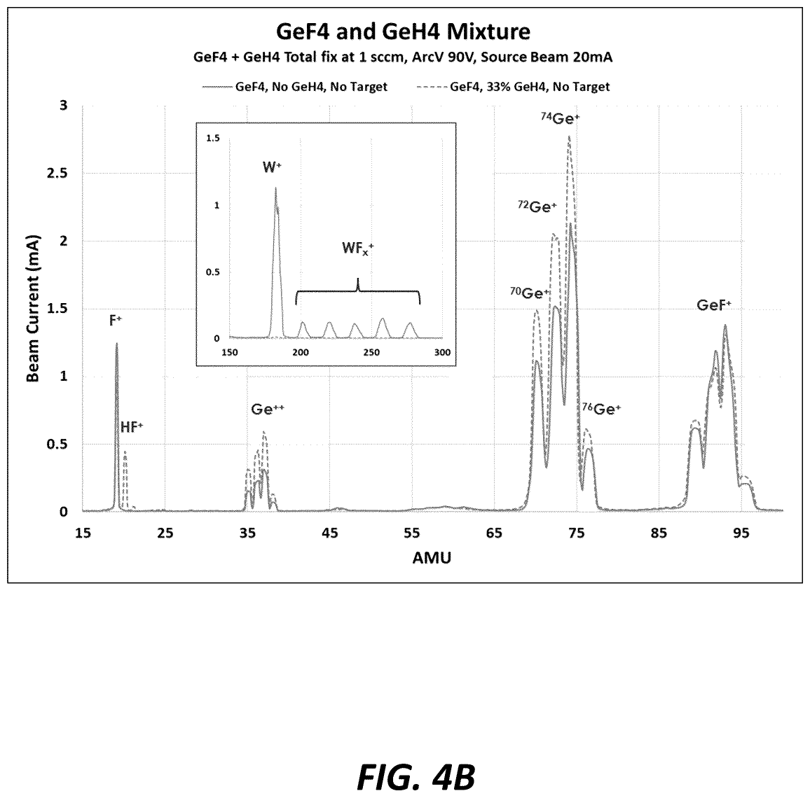

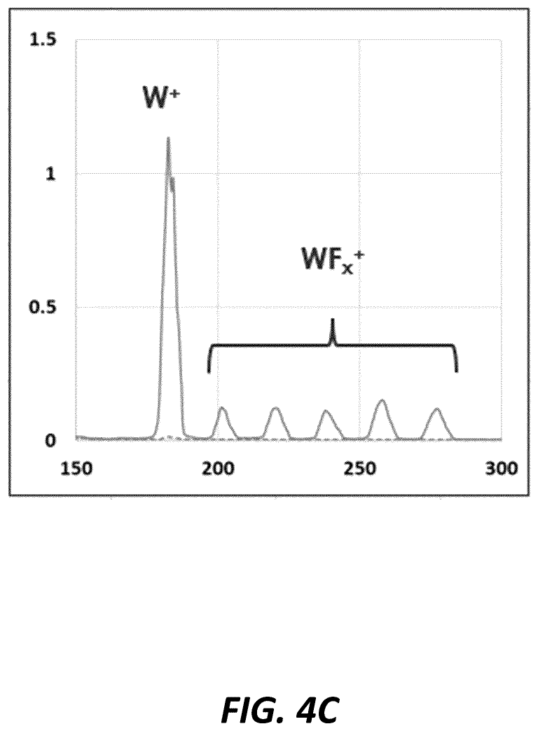

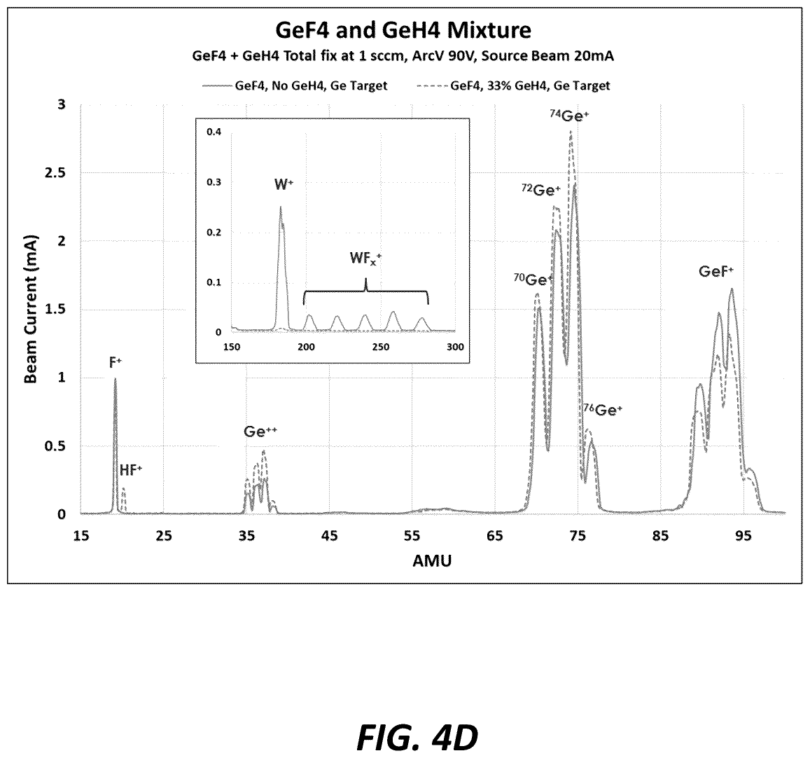

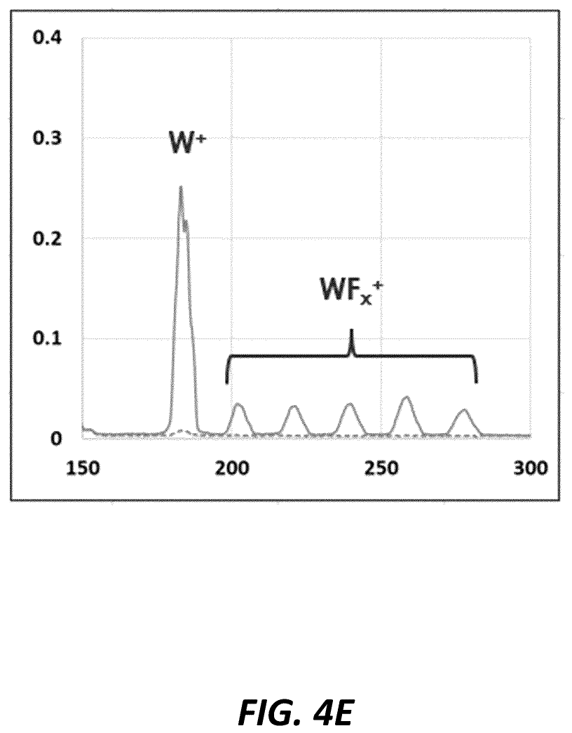

A mixture of GeF₄ and GeH₄ was flowed into an arc reaction chamber containing a target material comprising Ge at a fixed flow rate of 1 sccm. The performance of GeF₄/GeH₄ with the Ge target material was compared to a control composition of GeF₄/GeH₄ flowed into an arc reaction chamber containing no target material. The beam current in mA was measured at different volume percentages of GeH₄ relative to the total volume of GeF₄ and GeH₄ as shown in FIG. 4A. The arc power was 90V and source beam was 20 mA. As shown, the GeF₄/GeH₄ with the Ge target material showed markedly improved beam current relative to the control composition from all tested volume percentages of GeH₄ relative to the total volume of GeF₄ and GeH₄.

FIG. 4B is a graph showing the beam spectrum of GeF₄/GeH₄ compared to GeF₄, where neither beam was flowed into an arc chamber containing a Ge target material. As shown in FIG. 4B, the beam spectrum of GeF₄ was compared to that of GeF₄ with 33% volume GeH₄ relative to the total volume of GeF₄ and GeH₄. As shown, the GeF₄/GeH₄ showed markedly improved beam current relative to the control composition and showed markedly reduced W⁺ and WFₓ⁺ peaks, as shown in FIG. 4C.

FIG. 4D is a graph showing the beam spectrum of GeF₄/GeH₄ compared to GeF₄, where both beams were flowed into an arc chamber containing a Ge target material. As shown in FIG. 4D, the beam spectrum of GeF₄ was compared to that of GeF₄ with 33% volume GeH₄ relative to the total volume of GeF₄ and GeH₄. As shown, the GeF₄/GeH₄ showed markedly improved beam current relative to the control composition and showed markedly reduced W⁺ and WFₓ⁺ peaks, as shown in FIG. 4E.

### Aspects

Various Aspects are described below. It is to be understood that any one or more of the features recited in the following Aspect(s) can be combined with any one or more other Aspect(s).
Aspect 1. An ion implantation system, comprising:
a gas supply assembly comprising at least one gas supply vessel in fluid communication with an arc chamber,
   wherein the gas supply assembly is configured to supply a gas component comprising at least one of GeF₄, GeH₄, H₂, a fluorine-containing gas, or any combination thereof;
      wherein, when the gas component is supplied from the at least one gas supply vessel to the arc chamber for implantation into a substrate, a beam current of Ge ions generated from the gas component is greater than a beam current of Ge ions generated from a control gas component.
Aspect 2. The ion implantation system according to Aspect 1, wherein the at least one gas supply vessel comprises a first vessel comprising GeF₄, and a second vessel comprising GeH₄.
Aspect 3. The ion implantation system according to any one of Aspects 1-2, wherein the at least one gas supply vessel comprises a single vessel comprising GeF₄ and GeH₄.
Aspect 4. The ion implantation system according to any one of Aspects 1-3, wherein the arc chamber comprises a target material comprising Ge.
Aspect 5. The ion implantation system according to Aspect 4, wherein the target material comprising Ge comprises at least one of a pure germanium, a germanium isotope, a silicon germanium, or any combination thereof.
Aspect 6. The ion implantation system according to any one of Aspects 1-5, wherein the arc chamber is at least partially formed of a target material comprising Ge.
Aspect 7. The ion implantation system according to any one of Aspects 1-6, wherein the arc chamber comprises a container of a target material comprising Ge.
Aspect 8. The ion implantation system according to any one of Aspects 1-7, wherein the arc chamber comprises a liner at least partially formed of a target material comprising Ge.
Aspect 9. The ion implantation system according to any one of Aspects 1-8, wherein the gas component comprises GeF₄, GeH₄, and H₂.
Aspect 10. The ion implantation system according to any one of Aspects 1-9, wherein the gas component comprises GeH₄ and the fluorine-containing gas.
Aspect 11. The ion implantation system according to any one of Aspects 1-10, wherein the gas component comprises GeF₄; and wherein the arc chamber comprises a target material comprising Ge.
Aspect 12. The ion implantation system according to any one of Aspects 1-11, wherein the gas component comprises GeH₄; and wherein the arc chamber comprises a target material comprising Ge.
Aspect 13. The ion implantation system according to any one of Aspects 1-12, wherein the gas component comprises GeF₄, GeH₄, and H₂; and wherein the arc chamber comprises a target material comprising Ge.
Aspect 14. The ion implantation system according to any one of Aspects 1-13, wherein the gas component comprises:
   20% to 95% by volume of GeF₄ based on a total volume of the gas component;
   5% to 80% by volume of GeH₄ based on the total volume of the gas component;
   up to 70% by volume of H₂ based on the total volume of the gas component;
and
   up to 90% by volume of the fluorine-containing gas based on the total volume of the gas component.
Aspect 15. The ion implantation system according to any one of Aspects 1-14, wherein the GeF₄ is isotopically-enriched GeF₄.
Aspect 16. A method of ion implantation, comprising:
   flowing a gas component into an arc chamber,
      wherein the gas component comprises at least one of GeF₄, GeH₄, H₂, a fluorine-containing gas, or any combination thereof; and
   generating Ge ions from the gas component for implantation into a substrate;
      wherein a beam current of the Ge ions generated from the gas component is greater than a beam current of Ge ions generated from a control gas component.
Aspect 17. The method according to Aspect 16, wherein the flowing comprises flowing the ionizable gas mixture at a flowrate of 0.1 to 5 sccm.
Aspect 18. The method according to any one of Aspects 16-17, wherein the Ge ions are generated without applying a bias voltage.
Aspect 19. The method according to any one of Aspects 16-18, wherein the at least one gas supply vessel comprises a first vessel comprising GeF₄, and a second vessel comprising GeH₄.
Aspect 20. The method according to any one of Aspects 16-19, wherein the at least one gas supply vessel comprises a single vessel comprising GeF₄ and GeH₄.
Aspect 21. The method according to any one of Aspects 16-20, wherein the arc chamber comprises a target material comprising Ge.
Aspect 22. The method according to any one of Aspects 16-21, wherein the target material comprising Ge comprises at least one of a pure germanium, a germanium isotope, a silicon germanium, or any combination thereof.
Aspect 23. The method according to any one of Aspects 16-22, wherein the arc chamber is at least partially formed of a target material comprising Ge.
Aspect 24. The method according to any one of Aspects 16-23, wherein the arc chamber comprises a container of a target material comprising Ge.
Aspect 25. The method according to any one of Aspects 16-24, wherein the arc chamber comprises a liner at least partially formed of a target material comprising Ge.
Aspect 26. The method according to any one of Aspects 16-25, wherein the gas component comprises GeF₄, GeH₄, and H₂.
Aspect 27. The method according to any one of Aspects 16-26, wherein the gas component comprises GeH₄ and the fluorine-containing gas.
Aspect 28. The method according to any one of Aspects 16-27, wherein the gas component comprises GeF₄; and wherein the arc chamber comprises a target material comprising Ge.
Aspect 29. The method according to any one of Aspects 16-28, wherein the gas component comprises GeH₄; and wherein the arc chamber comprises a target material comprising Ge.
Aspect 30. The method according to any one of Aspects 16-29, wherein the gas component comprises GeF₄, GeH₄, and H₂; and wherein the arc chamber comprises a target material comprising Ge.
Aspect 31. The method according to any one of Aspects 16-30, wherein the gas component comprises:
   20% to 95% by volume of GeF₄ based on a total volume of the gas component;
   5% to 80% by volume of GeH₄ based on the total volume of the gas component;
   up to 70% by volume of H₂ based on the total volume of the gas component;
and
   up to 90% by volume of the fluorine-containing gas based on the total volume of the gas component.
Aspect 32. The method according to any one of Aspects 16-31, wherein the GeF₄ is isotopically-enriched GeF₄.
Aspect 33. An ion implantation system, comprising:
   a gas supply assembly comprising at least one gas supply vessel in fluid communication with an arc chamber,
      wherein the arc chamber comprises a target material comprising Ge;
      wherein the gas supply assembly is configured to supply a gas component comprising GeF₄,
         wherein, when the gas component is supplied from the at least one gas supply vessel to the arc chamber for implantation into a substrate, a beam current of Ge ions generated from the gas component, in the presence of the target material, is greater than a beam current of Ge ions generated from the gas component, in the absence of the target material.
Aspect 34. The ion implantation system according to Aspect 33, wherein the gas component further comprises H₂.
Aspect 35. The ion implantation system according to any one of Aspects 33-34, wherein the gas component further comprises GeH₄.
Aspect 36. The ion implantation system according to any one of Aspects 33-35, wherein at least one of GeF₄, GeH₄, or any combination thereof, comprises an isotopically enriched germanium.
Aspect 37. The ion implantation system according to any one of Aspects 33-36, wherein the target material comprises at least one of a pure germanium, an isotopically enriched germanium, a silicone germanium, or any combination thereof.
Aspect 38. An ion implantation system, comprising:
   a gas supply assembly comprising at least one gas supply vessel in fluid communication with an arc chamber,
      wherein the arc chamber comprises a target material comprising Ge;
      wherein the gas supply assembly is configured to supply a gas component comprising GeH₄,
         wherein, when the gas component is supplied from the at least one gas supply vessel to the arc chamber for implantation into a substrate, a beam current of Ge ions generated from the gas component, in the presence of the target material, is greater than a beam current of Ge ions generated from the gas component, in the absence of the target material.
Aspect 39. The ion implantation system according to Aspect 38, wherein the gas component further comprises H₂.
Aspect 40. The ion implantation system according to any one of Aspects 38-39, wherein the gas component further comprises GeF₄.
Aspect 41. The ion implantation system according to Aspect 40, wherein at least one of GeF₄, GeH₄, or any combination thereof, comprises an isotopically enriched germanium.
Aspect 42. The ion implantation system according to any one of Aspects 38-41, wherein the target material comprises at least one of a pure germanium, an isotopically enriched germanium, a silicone germanium, or any combination thereof.
Aspect 43. Any one of the Aspects 1-42, wherein the method and/or ion implantation system comprises enriched GeF₄, GeH₄, and a target material comprising enriched Ge, wherein each of the GeF₄, GeH₄, and target material is enriched in ⁷²Ge.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. An ion implantation system, comprising:
a gas supply assembly comprising at least one gas supply vessel in fluid communication with an arc chamber,
wherein the gas supply assembly is configured to supply a gas component comprising at least one of GeF₄, GeH₄, H₂, a fluorine-containing gas, or any combination thereof;
wherein, when the gas component is supplied from the at least one gas supply vessel to the arc chamber for implantation into a substrate, a beam current of Ge ions generated from the gas component is greater than a beam current of Ge ions generated from a control gas component.

2. The ion implantation system of claim 1, wherein the at least one gas supply vessel comprises a first vessel comprising GeF₄, and a second vessel comprising GeH₄.

3. The ion implantation system of claim 1, wherein the at least one gas supply vessel comprises a single vessel comprising GeF₄ and GeH₄.

4. The ion implantation system of claim 1, wherein the gas supply assembly further comprises an electrochemical cell configured to generate H₂.

5. The ion implantation system of claim 1, wherein the arc chamber comprises a target material comprising at least one of a pure germanium, an isotopically enriched germanium, a silicon germanium, or any combination thereof.

6. The ion implantation system of claim 1, wherein the arc chamber is at least partially formed of a target material comprising Ge.

7. The ion implantation system of claim 1, wherein the arc chamber comprises a container of a target material comprising Ge.

8. The ion implantation system of claim 1, wherein the arc chamber comprises a liner at least partially formed of a target material comprising Ge.

9. The ion implantation system of claim 1, wherein the gas component comprises GeF₄, GeH₄, and H₂.

10. The ion implantation system of claim 1, wherein the gas component comprises GeH₄ and the fluorine-containing gas.

11. The ion implantation system of claim 1, wherein the gas component comprises GeF₄; and wherein the arc chamber comprises a target material comprising Ge.

12. The ion implantation system of claim 1, wherein the gas component comprises GeH₄; and wherein the arc chamber comprises a target material comprising Ge.

13. The ion implantation system of claim 1, wherein the gas component comprises GeF₄, GeH₄, and H₂; and wherein the arc chamber comprises a target material comprising Ge.

14. The ion implantation system of claim 1, wherein the gas component comprises:
20% to 95% by volume of GeF₄ based on a total volume of the gas component;
5% to 80% by volume of GeH₄ based on the total volume of the gas component;
up to 70% by volume of H₂ based on the total volume of the gas component; and
up to 90% by volume of the fluorine-containing gas based on the total volume of the gas component.

15. The ion implantation system of claim 1, wherein at least one of GeF₄, GeH₄, or GeF₄ and GeH₄ comprises an isotopically enriched germanium.

16. A method of ion implantation, comprising:
flowing a gas component into an arc chamber,
wherein the gas component comprises at least one of GeF₄, GeH₄, H₂, a fluorine-containing gas, or any combination thereof; and
generating Ge ions from the gas component for implantation into a substrate;
wherein a beam current of the Ge ions generated from the gas component is greater than a beam current of Ge ions generated from a control gas component.

17. The method of claim 16, wherein the flowing comprises flowing the gas component at a flowrate of 0.1 to 5 sccm.

18. The method of claim 16, wherein the arc chamber comprises a target material comprising Ge.

19. The method of claim 18, wherein the target material comprising Ge comprises at least one of pure Ge, a germanium isotope, silicon germanium, or any combination thereof.

20. The method of claim 16, wherein the Ge ions are generated without applying a bias voltage.
